(19) United States
(12) Patent Application Publication
(10) Pub. No.: US 2025/0038638 A1
(43) Pub. Date: Jan. 30, 2025

(54) CURRENT SYNTHESIZER

(71) Applicant: Renesas Design (UK) Limited, Bourne End (GB)

(72) Inventors: Dantes JOHN, Munich (DE); Codrin HORA, Edinburgh (GB)

(73) Assignee: Renesas Design (UK) Limited, Bourne End (GB)

(21) Appl. No.: 18/675,769

(22) Filed: May 28, 2024

Related U.S. Application Data
(60) Provisional application No. 63/516,266, filed on Jul. 28, 2023.

(51) Int. Cl. H02M 1/00; H02M 3/158

(52) U.S. Cl. CPC H02M 1/0012; H02M 3/158

(57) ABSTRACT

A current synthesizer for a switching converter including an energy storage element and a first pass device, the switching converter configured to receive an input voltage and to provide an output voltage, the current synthesizer being configured to determine one or more first properties of a first current path of the switching converter, the first current path comprising the first pass device and the energy storage element, calculate a current flow through the energy storage element using the determined one or more first properties, and generate a digitized current signal, the digitized current signal being a digital representation of the current flow through the energy storage element, as calculated.

### CROSS-REFERENCE TO RELATED APPLICATION

This application claims the benefit of U.S. Patent Application No. 63/516,266, filed on Jul. 28, 2023. The entire disclosure of U.S. Patent Application No. 63/516,266 is incorporated by reference herein.

### BACKGROUND

The present disclosure relates to a current synthesizer for generating a digitized current signal. In particular, the present disclosure relates to a current synthesizer for a switching converter.

FIG. 1(a) is a schematic of a buck converter 100 comprising switches M_{HS}, M_{LS}; inverting driver 102, non-inverting driver 104; an inductor L, a resistance R_{L} and a capacitor C.

Control signal HS turns on M_{HS} if HS=1 (due to the inverting level shifter 102). The driver 102 is inverting and M_{HS} is a PMOS which is ON when its gate is LOW. Likewise control signal LS turns on M_{LS} if LS=1. This will drive the node SW to either V_{IN} or ground.

Due to the filter formed by L and C, the output voltage VOUT will be a filtered version of the voltage at SW with low ripple. R_{L} is a resistance that includes the inductor resistance and the routing resistance. To generalize, the drivers 102, 104 can obtain their power from rail that need not be V_{IN} or ground. Switches M_{HS} and M_{LS} are not simultaneously active during operation.

FIG. 1(b) is a schematic of a buck converter 106. The buck converter 106 is an alternative implementation of the buck converter 100 and comprises drivers 107, 109. The buck converter 106 uses a NMOS high-side switch M_{HS}. This typically uses a voltage V_{BOOT} for the gate drive, typically generated by a bootstrap circuit, though it could also be taken from any other voltage source.

FIG. 1(c) is a schematic of a digital buck converter 108 comprising a power stage 110, analog to digital converters (ADC) 112, 114, 116 and a controller 118. The power stage 110 comprises switches 120, 122, an inductor 124 and a capacitor 126. During operation, the switching converter receives an input voltage VIN and generates an output voltage VOUT.

While the power stage 110 and passive components (the inductor 124 and the capacitor 126) remain the same as for an analog buck converter (for example as shown in FIG. 1(a) and FIG. 1(b)), the ADC 116 converts the output voltage VOUT into a digital number. Optionally, the inductor current IL of the inductor 124, and the input voltage VIN can also be converted from analog to digital, depending on the digital control method.

We distinguish:
The switching frequency (FSW) of the buck converter 108, for example 2 MHz. FSW is equal to 1/TSW, where TSW is the switching period of the buck converter 108. FSW is the frequency of the power stage.
The processing frequency of the digital controller 118 (FS), for example about 100 MHz. FS is equal to 1/TS, where TS is the processing period of the controller 108. FS can also optionally be the sampling frequency of ADC 116.

Digital systems, such as the digital buck converter 108, may use a digital signal that is representative of a current flow through an energy storage element during operation. For example, a digitized current signal may be required by a controller for control of the switching operation of the digital switching converter.

In the present example, the digitized current signal is a digitized inductor current DIL, as provided by the ADC 112 converting an analog current signal indicative of the inductor current IL into a digital format.

The digitized inductor current DIL is provided to the controller 118, which uses the information on the inductor current IL to control the switching operation of the power switches 120, 122. The dependency of the control scheme on the inductor current means such a system may be referred to as a current mode converter using current mode control.

### SUMMARY

It is desirable to provide a system for providing a digitized current signal. For example, for switching converter control.

According to a first aspect of the disclosure there is provided a current synthesizer for a switching converter comprising an energy storage element and a first pass device, the switching converter configured to receive an input voltage and to provide an output voltage, the current synthesizer being configured to determine one or more first properties of a first current path of the switching converter, the first current path comprising the first pass device and the energy storage element, calculate a current flow through the energy storage element using the determined one or more first properties, and generate a digitized current signal, the digitized current signal being a digital representation of the current flow through the energy storage element, as calculated.

Optionally, the switching converter is one of a buck converter, a boost converter or a buck-boost converter.

Optionally, the energy storage element comprises an inductor.

Optionally, the first pass device is a first power switch or a first diode.

Optionally, the first power switch comprises a first transistor.

Optionally, the first transistor is a first metal oxide semiconductor field effect transistor (MOSFET).

Optionally, the first MOSFET is a p-type MOSFET or an n-type MOSFET.

Optionally, the one or more first properties of the first current path comprises a first current path resistance, a first current path voltage, and/or an inductance of the energy storage element, wherein the energy storage element comprises an inductor.

Optionally, the first current path resistance comprises an equivalent series resistance of the inductor and a first pass device resistance of the first pass device.

Optionally, the first pass device is a first power switch or a first diode.

Optionally, the one or more first properties of the first current path comprises a first current path resistance, a first current path voltage, and/or an inductance of the energy storage element, wherein the energy storage element comprises an inductor.

Optionally, the first current path resistance comprises an equivalent series resistance of the inductor and a first power switch resistance of the first power switch.

Optionally, the first power switch resistance is an on resistance of the first power switch or a body diode resistance of the first power switch.

Optionally, the first current path voltage comprises the output voltage and a first node voltage.

Optionally, the switching converter comprises a voltage detector configured to detect the output voltage and the first node voltage.

Optionally, the voltage detector comprises a first analog to digital converter configured to detect the first node voltage and a second analog to digital converter configured to detect the output voltage.

Optionally, the first node voltage is the input voltage or a ground voltage.

Optionally, the current synthesizer comprises a memory storage element comprising a lookup table for storing calibration data, wherein at least one of the first current path resistance and the inductance of the inductor are determined using at least a portion of the calibration data.

Optionally, the current synthesizer is configured to determine the inductance of the inductor by selecting the at least a portion of the calibration data based on the digitized current signal.

Optionally, the switching converter comprises a current sensor configured to sense a current flow through the inductor.

Optionally, the current synthesizer is configured to determine the inductance of the inductor by selecting the at least a portion of the calibration data based on the sensed current flow through the inductor.

Optionally, the current synthesizer is configured to determine the inductance of the inductor by interpolating using the calibration data.

Optionally, the current synthesizer is configured to determine the first current path resistance using one or both of a gate drive voltage and a temperature value.

Optionally, the current synthesizer is configured to determine the one or more first properties of the first current path of the switching converter at a first time step, calculate the current flow through the energy storage element at a second time step using the determined one or more properties at the first time step, generate the digitized current signal comprising the digital representation of the current flow through the energy storage element at the second time step, as calculated.

Optionally, the one or more first properties of the first current path comprises a first current path resistance, a first current path voltage, and/or an inductance of the energy storage element, wherein the energy storage element comprises an inductor.

Optionally, the current synthesizer is configured to calculate the current flow through the energy storage element at the second time step by determine a first variable by multiplying the first current path resistance at the first time step and the current flow through the energy storage element at the first time step, determine a second variable by subtracting the first variable from the first current path voltage at the first time step, determine a third variable by multiplying the second variable with the time step difference between the second and first time steps, and dividing by the inductance, and determine the current flow through the energy storage element at the second time step by adding the current flow through the energy storage element at the first step to the third variable.

Optionally, the current synthesizer is configured to generate the digitized current signal when the switching converter is in at least one of a magnetization phase, a demagnetization phase, and/or an off phase.

Optionally, the digitized current signal has a linear profile or a non linear profile during the magnetization phase and/or the demagnetization phase.

Optionally, the switching converter comprises a second power switch, the current synthesizer being configured to determine the one or more first properties of the first current path of the switching converter during a first phase, calculate the current flow through the energy storage element using the determined one or more properties during the first phase, and generate a first portion of the digitized current signal during the first phase, using the calculated current flow during the first phase, determine one or more second properties of a second current path of the switching converter during a second phase, the second path comprising the second power switch and the energy storage element, calculate the current flow through the energy storage element using the determined one or more second properties, and generate a second portion of the digitized current signal during the second phase, using the calculated current flow during the second phase.

Optionally, the current synthesizer is configured to generate the digitized current signal when the switching converter is in at least one of a magnetization phase, a demagnetization phase, and/or an off phase.

Optionally, the digitized current signal has a linear profile or a non linear profile during the magnetization phase and/or the demagnetization phase.

Optionally, the switching converter comprises a controller configured to provide a second control signal to the second power switch, and the switching converter is operating in the first phase when the second power switch is in a first configuration and operating in the second phase when the second power switch is in a second configuration.

Optionally, the one or more first properties of the first current path comprises a first current path resistance, a first current path voltage, and/or an inductance of the energy storage element, wherein the energy storage element comprises an inductor; and the one or more second properties of the second current path comprises a second current path resistance, a second current path voltage, and/or the inductance of the energy storage element.

Optionally, the first current path resistance comprises an equivalent series resistance of the inductor and a first pass device resistance of the first pass device, and the second current path resistance comprises the equivalent series resistance of the inductor and a second power switch resistance of the second power switch.

Optionally, the first pass device is a first power switch or a first diode.

Optionally, the switching converter comprises a controller configured to provide a first control signal to the first power switch and a second control signal to the second power switch, and the switching converter is operating in the first phase when the first and second power switches are in a first configuration and operating in the second phase when the first and second power switches are in a second configuration.

Optionally, the first and/or second control signals are each pulse width modulation (PWM) signals.

Optionally, the current synthesizer is configured to detect at least one of the first and second control signals, and determine the one or more of the first properties and/or one or more of the second properties using the first and/or second control signals and/or determine whether the switching converter is operating in the first phase or the second phase.

Optionally, the one or more first properties of the first current path comprises a first current path resistance, a first current path voltage, and/or an inductance of the energy storage element, wherein the energy storage element comprises an inductor; and the one or more second properties of the second current path comprises a second current path resistance, a second current path voltage, and/or the inductance of the energy storage element.

Optionally, the first current path resistance comprises an equivalent series resistance of the inductor and a first power switch resistance of the first power switch, and the second current path resistance comprises the equivalent series resistance of the inductor and a second power switch resistance of the second power switch.

Optionally, the first power switch resistance is an on resistance of the first power switch or a body diode resistance of the first power switch, and/or the second power switch resistance is an on resistance of the second power switch or a body diode resistance of the second power switch.

Optionally, the first current path voltage comprises the output voltage and a first node voltage, and/or the second current path voltage comprises the output voltage and a second node voltage.

Optionally, the switching converter comprises a voltage detector configured to detect the output voltage and the first node voltage.

Optionally, the voltage detector comprises a first analog to digital converter configured to detect the first node voltage and a second analog to digital converter configured to detect the output voltage.

Optionally, the first node voltage is the input voltage and the second node voltage is a ground voltage.

Optionally, the current synthesizer comprises a memory storage element comprising a lookup table for storing calibration data, wherein at least one of the first current path resistance, the second current path resistance and the inductance of the inductor are determined using at least a portion of the calibration data.

Optionally, the current synthesizer is configured to determine the inductance of the inductor by selecting the at least a portion of the calibration data based on the digitized current signal.

Optionally, the switching converter comprises a current sensor configured to sense a current flow through the inductor.

Optionally, the current synthesizer is configured to determine the inductance of the inductor by selecting the at least a portion of the calibration data based on the sensed current flow through the inductor.

Optionally, the current synthesizer is configured to determine the inductance of the inductor by interpolating using the calibration data.

Optionally, the current synthesizer is configured to determine at least one of the first current path resistance and the second current path resistance using one or both of a gate drive voltage and a temperature value.

Optionally, the digitized current signal is for regulation of the switching converter, telemetry, load transient detection and/or load line modification.

According to a second aspect of the disclosure there is provided a power converter system comprising a current synthesizer, and a switching converter comprising an energy storage element and a first pass device, the switching converter configured to receive an input voltage and to provide an output voltage, wherein the current synthesizer is configured to determine one or more first properties of a first current path of the switching converter, the first current path comprising the first pass device and the energy storage element, calculate a current flow through the energy storage element using the determined one or more first properties, and generate a digitized current signal, the digitized current signal being a digital representation of the current flow through the energy storage element, as calculated.

Optionally, the first pass device is a first power switch or a first diode.

It will be appreciated that the power converter system of the second aspect may include features of the current synthesizer of the first aspect, and can include other features as described herein, in accordance with the understanding of the skilled person.

According to a third aspect of the disclosure there is provided a method of generating a digitized current signal using a current synthesizer for a switching converter, the switching converter comprising an energy storage element and first pass device, the switching converter configured to receive an input voltage and to provide an output voltage, the method comprising determining one or more first properties of a first current path of the switching converter, the first current path comprising the first pass device and the energy storage element, calculating a current flow through the energy storage element using the determined one or more first properties, and generating the digitized current signal, the digitized current signal being a digital representation of the current flow through the energy storage element, as calculated.

Optionally, the first pass device is a first power switch or a first diode.

It will be appreciated that the method of the third aspect may include providing and/or using features set out in relation to the first and/or second aspect, and may include other features as described herein, in accordance with the understanding of the skilled person.

### BRIEF DESCRIPTION OF THE DRAWINGS

The disclosure is described in further detail below by way of example and with reference to the accompanying drawings in which:

FIG. 1(a) is a schematic of a buck converter; FIG. 1(b) is a schematic of a further buck converter, FIG. 1(c) is a schematic of a digital buck converter;

FIG. 2(a) is a schematic of an apparatus comprising a current synthesizer for a switching converter in accordance with a first embodiment of the present disclosure, FIG. 2(b) is a schematic of a specific embodiment of the apparatus comprising a specific embodiment of the current synthesizer, in accordance with a second embodiment of the present disclosure, FIG. 2(c) is a schematic of a specific embodiment of the apparatus, where the apparatus is a digital buck converter system comprising the switching converter and the current synthesizer, in accordance with a third embodiment of the present disclosure, FIG. 2(d) is a graph of the inductor current IL varying with time during operation of the buck converter of FIG. 2(c) for an ideal inductor, FIG. 2(e) is a schematic of a further digital buck converter system comprising the switching converter and the current synthesizer, in accordance with a fourth embodiment of the present disclosure, FIG. 2(f) is a schematic of an apparatus comprising a specific embodiment of the current synthesizer in accordance with a fifth embodiment of the present disclosure;

FIG. 3(a) is a current-voltage graph showing a non-linear relationship between voltage and current for a diode, FIG. 3(b) is a current-inductance graph showing inductor saturation, FIG. 3(c) is a 1/L-current graph showing how interpolation may be applied for different currents, FIG. 3(d) shows a graph of the current for the switching waveform;

FIG. 4 is a schematic of an apparatus comprising a specific embodiment of the current synthesizer in accordance with a sixth embodiment of the present disclosure; and

FIG. 5(a) is a schematic of a specific embodiment of the apparatus, where the apparatus is a digital boost converter system comprising the switching converter and the current synthesizer, in accordance with a seventh embodiment of the present disclosure, FIG. 5(b) is a schematic of a specific embodiment of the apparatus, where the apparatus is an inverting buck-boost converter system comprising the switching converter and the current synthesizer, in accordance with a eighth embodiment of the present disclosure, FIG. 5(c) is a schematic of a specific embodiment of the apparatus, where the apparatus is a positive buck-boost converter system comprising the switching converter and the current synthesizer, in accordance with a ninth embodiment of the present disclosure, FIG. 5(d) is a schematic of a specific embodiment of the apparatus 200, where the apparatus is a buck converter system, in accordance with a tenth embodiment of the present disclosure.

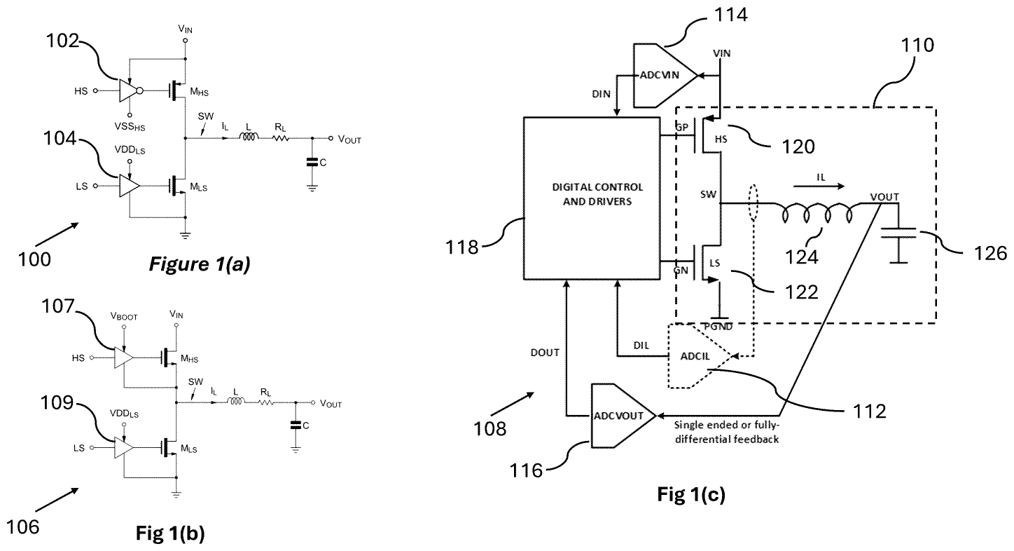

### DETAILED DESCRIPTION

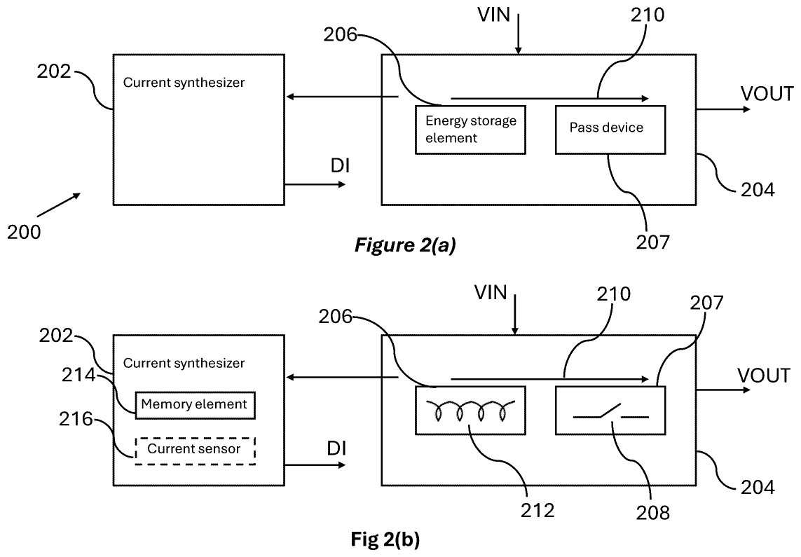

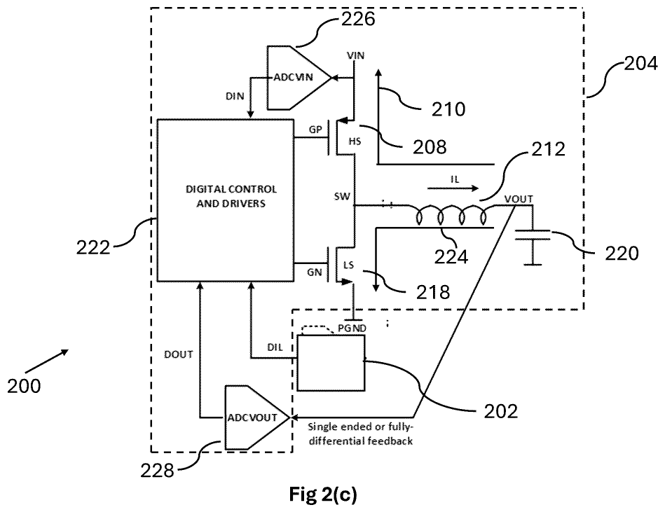

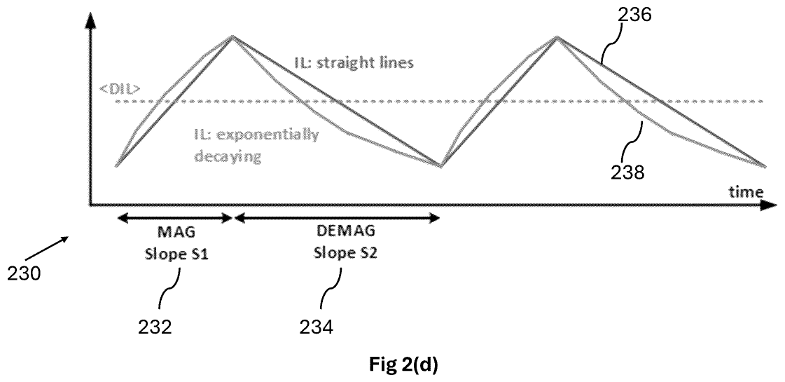

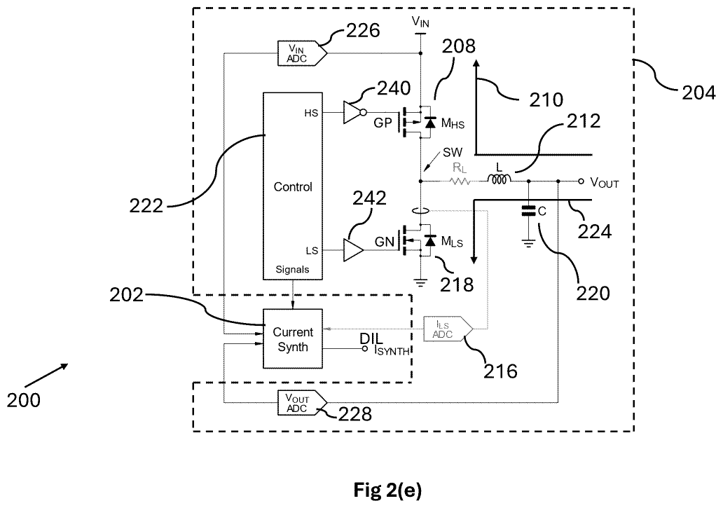

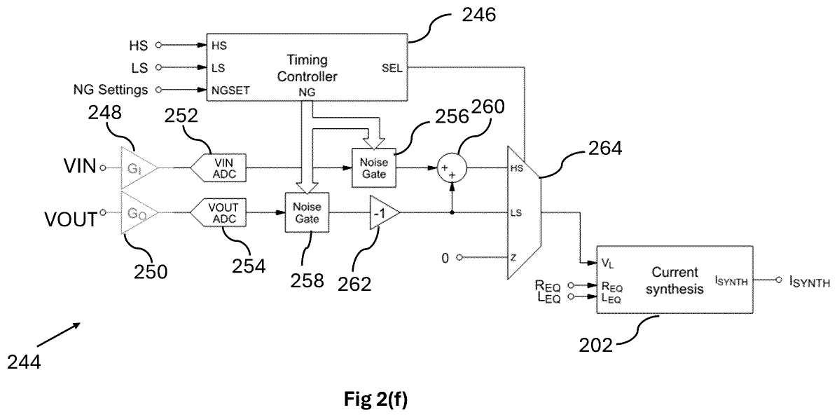

FIG. 2(a) is a schematic of an apparatus 200 comprising a current synthesizer 202 for a switching converter 204 in accordance with a first embodiment of the present disclosure. The switching converter 204 comprises an energy storage element 206 and a pass device 207. During operation, the switching converter 204 receives an input voltage VIN and provides an output voltage VOUT. The current synthesizer 202 may be referred to as a digital current synthesizer. The pass device 207 may, for example, be a power switch or a diode.

The switching converter 204 may, for example, be a buck converter, a boost converter or a buck-boost converter. The energy storage element 206 may comprise an inductor. The power switch 208 may comprise a transistor, such as a metal oxide semiconductor field effect transistor (MOSFET). The MOFET may, for example, be a p-type MOSFET or an n-type MOSFET. In a specific embodiment, the switching converter 204 may comprise two or more power switches, each comprising a transistor.

The current synthesizer 202 is configured to determine one or more first properties of a current path 210 of the switching converter 204. The current path 210 comprises the power switch 208 and the energy storage element 206.

The one or more first properties of the current path may, for example, comprise: a current path resistance of the current path 210, a current path voltage of the current path 210 and/or an inductance of the energy storage element 206, where the energy storage element 206 is an inductor.

The current path resistance may comprise an equivalent series resistance DCR of the energy storage element 206, where the energy storage element is an inductor and a pass device resistance of the pass device 207.

For a specific embodiment, where the pass device 207 is a power switch, the current path resistance may comprise the equivalent series resistance DCR of the energy storage element 206, where the energy storage element is an inductor, and the power switch resistance of the power switch 208. The power switch resistance may, for example, be the on resistance of the power switch 208.

The current synthesizer 202 is further configured to calculate a current flow through the energy storage element 206 using the one or more first properties, as determined.

The current synthesizer 202 is further configured to generate a digitized current signal DI. The digitized current signal is a digital representation of the current flow through the energy storage element 206, as calculated.

The digitized current signal DI can be used to provide accurate, high-bandwidth inductor current information in a switching converter.

In specific embodiments, the digitized current signal DI may be used for one or more of the following: regulation of the switching converter 204, telemetry, load transient detection and/or load line modification.

In a specific embodiment, the current synthesizer 202 may be configured to determine the one or more first properties of the current path 210 at a first time step, and then calculate the current flow through the energy storage element 206 at a second time step using the one or more properties as determined at the first time step, where the second time step is after the first time step. The current synthesizer 202 may be further configured to generate the digitized current signal DI comprising the digital representation of the current flow through the energy storage element 206 at the second time step, based on the calculation.

The current synthesizer 202 may be configured to repeat the process for subsequent time steps, such that the one or more first properties are determined for an initial time step, and then used for the calculation and then generation of the next time step, then repeated, to sequentially construct the digitized current signal DI as it varies with time.

FIG. 2(b) is a schematic of a specific embodiment of the apparatus 200 comprising a specific embodiment of the current synthesizer 202, in accordance with a second embodiment of the present disclosure. In the present embodiment, the energy storage element 206 is an inductor 212, and the pass device 207 is a power switch 208.

The current synthesizer 202 comprises a memory storage element 214 for storing a lookup table of calibration data. The current synthesizer 202 is configured to determine the current path resistance of the current path 210 and/or the inductance of the inductor 212 using at least a portion of the calibration data stored in the memory storage element 214.

The calibration data may comprise inductance values for current flows, such that the current synthesizer 202 may then select the necessary calibration data from the lookup table based on the digitized current signal DI to determine the inductance of the inductor 212. In a specific embodiment, the determination of the inductance of the inductor 212 may be achieved by interpolating between two or more data points within the calibration data.

In a specific embodiment, the current synthesizer 202 comprises a current sensor 216 that is configured to sense a current IL, which is the current flow through the inductor 212.

In a specific embodiment the measured current IL may be used to background calibrate the synthetic current DI.

In a specific embodiment, the calibration data may comprise inductance values for measured current flows, such that the current synthesizer 202 may then select the necessary calibration data from the lookup table based on the sensed current IL to determine the inductance of the inductor 212. In a specific embodiment, the determination of the inductance of the inductor 212 may be achieved by interpolating between two or more data points within the calibration data.

In a further embodiment, the current synthesizer 202 may be configured to determine the current path resistance of the current path 210 using one or both of a gate drive voltage and a temperature value in addition to the calibration data.

FIG. 2(c) is a schematic of a specific embodiment of the apparatus 200, where the apparatus is a digital buck converter system comprising the switching converter 204 and the current synthesizer 202, in accordance with a third embodiment of the present disclosure. In the present embodiment, the switching converter 204 is a buck converter.

In the present example, the digitized current signal DI is a digitized inductor current DIL, which is a digital representation of the current flow IL through the inductor 212. The current synthesizer 202 may generate the digitized inductor current DIL by calculating the current flow IL through the inductor 212.

The switching converter 204 comprises a switch 218 and a capacitor 220. The switching converter further comprises a controller 222 for driving the switching operation of the switch 208 and the switch 218 using a control signal GP and a control signal GN, respectively. The control signals GP, GN may be pulse width modulation (PWM) signals.

The switches 208, 218 may be referred to as pass devices. Both switches 208, 218 can be turned off during operation (for example for PFM/DCM or diode braking), but simultaneously on may damage the device.

During operation, the controller 222 provides the PWM switching signals to the switching devices 208, 218 alternately through drivers (not shown). The drivers are used to provide signals GP, GN of sufficient strength and voltage levels to turn on/off the pass devices 208, 218 quickly and safely. The signals GP and GN may be referred to as “gate drive voltages”.

A buck converter converts the input voltage VIN to a lower output voltage VOUT. It does this by alternately connecting a SW node to the input voltage node or ground and then using the inductor 212 and the capacitor 220 to filter out the resulting ripple.

The switching converter 204 operates in a first phase when the switches 208, 218 are in a first configuration and operates in a second phase when the switches 208, 218 are in a second configuration.

In the present embodiment, there is shown the current path 210 and a current path 224 comprising the switch 218 and the inductor 212. The current path 210 is the path of current flow during the magnetization phase of the operation of the switching converter 204, when the switch 208 is closed and the switch 218 is open.

The current path 224 is the path of current flow during the demagnetization phase of the operation of the switching converter 204, when the switch 218 is closed and the switch 208 is open.

In a specific embodiment, a first property as determined by the current synthesizer 202 during operation may be the current path voltage of one of the current paths 210, 224. The current path voltage comprises the output voltage VOUT and a node voltage, with the node voltage being the input voltage VIN for the current path 210 and the ground voltage PGND for the current path 224.

The switching converter 204 comprises a voltage detector configured to detect the output voltage VOUT and the node voltage, being the input voltage VIN in the present example. The voltage detector comprises an analog to digital converter (ADC) 226 configured to detect the input voltage VIN and an analog to digital converter (ADC) 228 configured to detect the output voltage VOUT.

The digitized current signal DI may be generated when the switching converter 204 is in a magnetization phase, for example by determining the current path voltage of the current path 210; the demagnetization phase, for example by determining the current path voltage of the current path 224; or an off phase.

The digitized current signal DI may have a linear profile or a non linear profile during the magnetization phase and/or the demagnetization phase.

In a specific embodiment, the current synthesizer 202 may be configured to generate the digitized current signal DI during a first phase, for example the magnetization phase, through determination and calculation based on one or more properties of the current path 210. The current synthesizer 202 may be configured to continue to generate the digitized current signal DI during a second phase, for example the demagnetization phase, through determination and calculation based on one or more properties of the current path 224. The procedure may then repeat as the switching converter 204 switches between magnetization and demagnetization phases.

One of the one or more properties of the current path 210 used for the current flow calculation during the magnetization phase may be the current path resistance which comprises the equivalent series resistance DCR of the inductor 212, and the power switch resistance of the power switch 208. The power switch resistance may, for example, be the on resistance of the power switch 208.

Another of the one or more properties of the current path 210 used for the current flow calculation during the magnetization phase may be the current path voltage of the current path 210, which comprises the output voltage VOUT and the input voltage VIN.

One of the one or more properties of the current path 224 used for the current flow calculation during the demagnetization phase may be the current path resistance which comprises the equivalent series resistance DCR of the inductor 212, and the power switch resistance of the power switch 218. The power switch resistance may, for example, be the on resistance of the power switch 218.

Another of the one or more properties of the current path 224 used for the current flow calculation during the demagnetization phase may be the current path voltage of the current path which comprises the output voltage VOUT and the ground voltage PGND.

It will be appreciated that although the present embodiment relates to the generation of the digitized current signal DI during operation of a buck converter, further embodiments of the current synthesizer 202 may be applied to other switching converters, and during operational phase of these other switching converters, in accordance with the understanding of the skilled person.

FIG. 2(d) is a graph 230 of the inductor current IL varying with time during operation of the buck converter of FIG. 2(c). During operation, the inductor 212 switches between coupling to the input voltage VIN via the switch 208 (the magnetization phase, labelled by numeral 232) and coupling to ground PGND via the switch 218 (the demagnetization phase, labelled by numeral 234).

It will be appreciated that FIG. 2(d) is for an ideal inductor, whereas real inductors (for example with ferromagnetic cores), may exhibit a different variation.

The graph shows a first trace 236 showing an idealised inductor current. The inductor current IL may have an idealised shape that made of straight lines and is as is used in U.S. Pat. No. 9,419,627B2 and U.S. Pat. No. 9,667,260B2. The graph also shows a second trace 238 showing a more realistic current profile where the slope of each phase has a non-linear shape (exponential decay for the falling slope).

Note that the timing diagrams are continuous time and continuous data to aid in the clarity of the explanation.

It will be appreciated that in specific applications, the inductor saturation may dominate over the exponential decaying factor such that the traces 236, 238 will be “flipped” horizontally with respect to the current FIG. 2(d).

For some switching converters, a straight-line approximation of the inductor current IL can be sufficient for an effective control scheme. However, having a more accurate, non-linear, digitized inductor current DIL waveform is desirable as it can ensure more precise current control. Furthermore, a digitized inductor current DIL having improved accuracy can be used for additional applications beyond just regulation, such as for over current protection.

FIG. 2(e) is a schematic of a further digital buck converter system comprising the switching converter 204 and the current synthesizer 202, in accordance with a fourth embodiment of the present disclosure. In the present embodiment, the switching converter 204 is a buck converter.

In the present example, the digitized current signal DI is a digitized inductor current DIL, which is a digital representation of the current flow through the inductor 212. The current synthesizer 202 may generate the digitized inductor current DIL by calculating the current flow IL through the inductor 212.

In the present example, the drivers 240, 242 for providing the control signals GP, GN, are shown.

The power supply to the drivers 240, 242 may, for example, be the existing supplies (the input voltage VIN and the ground rail), or other intermediate rails depending on the needs of the application and the pass devices.

It will be appreciated that although the switch 208 in the present embodiment is PMOS, this could alternatively be an NMOS with appropriate drive circuitry (for example, a bootstrap cap).

The current synthesizer 202 may comprise the memory storage element 214 (not shown in the present Figure) for storing the lookup table of calibration data. The current synthesizer 202 may be configured to determine the current path resistance of the current path 210 and/or the current path resistance of the current path 224 and/or the inductance of the inductor 212 using at least a portion of the calibration data stored in the memory storage element 214.

In a further embodiment, the current synthesizer 202 may be configured to determine the current path resistance of the current path 210 and/or the current path resistance of the current path 224 using one or both of a gate drive voltage and a temperature value in addition to the calibration data.

The current path resistance of a given path may comprise the equivalent series resistance DCR of the inductor 212, and the power switch resistance of the power switch in the path. The power switch resistance may, for example, be the on resistance of the power switch or the body diode resistance of the power switch.

In the present embodiment, the current synthesizer 202 is configured to detect at least one of the control signals GP, GN. The current synthesizer 202 may then determine the properties for the current flow calculation based on the detected control signals. Additionally, or alternatively, the current synthesizer 202 may determine the current operational phase of the switching converter 204 using the detected control signals. Additionally, or alternatively, the current synthesizer 202 may receive the information relating to the switching status of one or both of the switches 208, 218 by a signal other than the control signals GP, GN from the controller 222. The current synthesizer 202 may also receive the voltages VIN, VOUT through the corresponding ADCs 226, 228. Using this information, the current synthesizer 202 can estimate the voltage seen across the presently active current path 210, 224—being the current path voltage as previously discussed—during a given phase at different points in time.

In specific embodiments, the voltage across the inductor 212 (being the current path voltage) may be computed from the knowledge of voltages at different nodes in the circuit, as discussed previously, along with the knowledge of the pulse width modulation (PWM) signal applied to control of the switches 208, 218.

In specific embodiments, the voltages VIN, VOUT may be measured through separate ADCs 226, 228 which may also be used for voltage regulation, and the PWM signal may be known if it is generated by a modulator within the same system as the current synthesizer 202.

In a specific embodiment, the current synthesizer 202 may compute the synthetic current DI on each compute step using the voltages that are currently present across the inductor 212 and the value of REQ and L along with period of the computation clock (being TS). In further embodiments, diode effects and/or time delays may also be considered in the computation.

If the voltage across a current path is known, the current flow through the inductor 212 in the discrete time domain (so clocked at Tₛ, which may be the processing period of the controller 222) may be calculated as follows:

$$DI [ n ] = DI [ n - 1 ] {e}^{\frac{- {T}_{s}}{τ}} + \frac{V [ n - 1 ]}{REQ} ( 1 - {e}^{\frac{- {T}_{s}}{τ}} ) \qquad ( 1 )$$

$$where :$$

$$τ = \frac{L}{REQ} \qquad ( 2 )$$

n denotes the sample number, such that DI[n] is the digitized current signal DI at a second time step, and DI[n−1] is the digitized current signal DI at a first time step, the second time step occurring after the first time step. Tₛ is the time step for the computation, which may be the processing period of the controller 222 as discussed previously; V[n−1] is the current path voltage across the current path at the first time step; REQ is the current path resistance; and L is the inductance of the inductor 212.

The current path resistance REQ may be the total resistance seen in the path which includes the resistance of the relevant switch (the on resistance of the switch 208 when the switch 208 is on, and the on resistance of the switch 218 when the switch 218 is on), the DC resistance of the inductor 212 (DCR), and other routing resistances in the currently active path. The REQ will thus change depending on the state the switches 208, 218.

Such estimations also consider practical delays that may occur in the circuit. Such delays include delays in the drivers 240, 242 and the turn on/off delays of the pass devices 208, 218. The delays may be affected by drive voltages, process corners during manufacture, and die temperature. The delay values used may be generated from lookup tables using data available during factory trimming, and from voltage and temperature sensors on the device. Interpolation may also be used to determine value between measured points.

With the knowledge of the voltage across the inductor 212, the present value of the current DI[n−1], the values of REQ and L, and the interval of computation Tₛ, the next value of current DI[n] can be computed. In specific embodiments of the present disclosure, this allows the current synthesizer 202 to predict the value of current with any resolution (both time and amplitude) and no latency.

The ADC 216 functions as a current sense ADC and is able to give a measure of current in the switch 218 at a given sample rate. This may be used for calibration of parameters REQ and L.

While the present embodiment shows a low-side current sense, it is also possible to use a high-side current sense that measures the current through the switch 208.

Alternatively, or additionally, a separate current sense can be used where a small resistance in series with the inductor 212 is used to measure the current through the inductor 212.

Depending on the direction of current, if both switches 208, 218 are turned off, the body diodes of the switches 208, 218 may turn on. This will add an additional voltage of the diode forward voltage, as well as the diode equivalent resistance instead of the switch resistance. The particular diode that will appear in the current path will depend on the direction of the current. If the current if flowing towards the VOUT, the switch 218 body diode turns on, else the switch 208 body diode turns on. The forward voltage and the forward resistance of the path 210 may be denoted as VDHS and RDHS, respectively and the forward voltage and forward resistance of the path 224 may be denoted as VDLS and RDLS, respectively.

Current direction in all the equations assumes that positive current flows from left to right in the buck circuit i.e. towards VOUT.

V[n−1] in equation (1) implies the value of the analog voltages, VIN and VOUT one computation step before the current computation. For simplicity we assume that the voltages are steady, which they are in the real steady state case.

Equation (1) may be simplified as follows for a case where Tₛ is much less than τ, using the expansion of e^{x}, and omitting the higher terms, we get:

$$DI [ n ] = DI [ n - 1 ] + ( V [ n - 1 ] - DI [ n - 1 ] REQ ) \frac{{T}_{S}}{L} \qquad ( 2 )$$

Equation (2) may be summarised as follows, where the calculation of the current flow through the inductor 212 at the second time step is calculated by:
Multiplying the current path resistance REQ and the current flow through the energy storage element DI[n−1], to provide DI[n−1]REQ.
Subtracting DI[n−1]REQ from the current path voltage V[n−1], to provide V[n−1]−DI[n−1]REQ.
Multiplying V[n−1]−DI[n−1]REQ with the time step difference between the second and first time steps (being Tₛ), and dividing by the inductance L, to provide (V[n−1]−DI[n−1]REQ)Tₛ/L
Adding the current flow through the energy storage DI[n−1] to (V[n−1]−DI[n−1]REQ)Tₛ/L, to provide equation (1).

Note that the current path resistance REQ is dependent on the current path during a given phase. During the magnetization phase, the current path resistance may be denoted as RMAG and during the demagnetization phase, the current path resistance may be denoted as RDEMAG. The variable terms RMAG and RDEMAG may be the non-linear corrections to ideal slopes for the magnetization phase, and the demagnetization phase, respectively.

During the magnetization phase, when the switch 208 is turned on, equation (2) may be written as:

$$DI [ n ] = DI [ n - 1 ] - DI [ n - 1 ] RMAG \frac{{T}_{S}}{L} + ( VIN - VOUT ) \frac{{T}_{S}}{L} \qquad ( 3 )$$

and during the demagnetization phase, when the switch 218 is turned on, equation (2) may be written as:

$$DI [ n ] = DI [ n - 1 ] - DI [ n - 1 ] RDEMAG \frac{{T}_{S}}{L} - VOUT \frac{{T}_{S}}{L} \qquad ( 4 )$$

VIN and VOUT in equations (3) and (4) may be digital signals, being the digital versions of their respective voltages as acquired by their respective ADCs 226, 228 and provided to the current synthesizer 202.

As can be observed by equations (3) and (4), depending on the state of the switches 208, 218 the estimated voltage across the inductor 212 is calculated. If the switch 208 is turned on, V[n−1]=(VIN−VOUT), else if the switch 218 is turned on, V[n−1]=(−VOUT). Both switches 208, 218 may be turned off in the DCM mode.

The current path resistance of the path 210, being the current path resistance during the magnetization phase and denoted as “RMAG” may comprise the equivalent series resistance DCR of the inductor 212, and the power switch resistance of the power switch 208 (denoted “RHS”), and may be written as follows:

$$RMAG = DCR + RHS + RHStrace \qquad ( 5 )$$

where RHStrace denotes all trace resistances associated with the high side.

The current path resistance of the path 224, being the current path resistance during the demagnetization phase and denoted as “RDEMAG” may comprise the equivalent series resistance DCR of the inductor 212, and the power switch resistance of the power switch 218 (denoted “RLS”), and may be written as follows:

$$RDEMAG = DCR + RLS + RLStrace \qquad ( 6 )$$

where RLStrace denotes all trace resistances associated with the low side.

The equivalent series resistance DCR is denoted as RL in the Figure, and may denote the remaining resistances common to both paths.

RHS and RLS may denote the on resistance of the switch 208 and the switch 218, respectively

In a further embodiment, there may be provided a single value of REQ for both phases, as opposed to the separate values presented in Equations (5) and (6). For a single value embodiment, REQ may be as follows:

$$REQ = DCR + D \times RHS + ( 1 - D ) \times RLS \qquad ( 7 )$$

where D is the converter's duty cycle.

It will be appreciated that the digitized current signal DI may have the profile shown by the trace 236 by using a straight line approximation by setting RMAG=RDEMAG=0 for equations (3) and (4). It will be appreciated that this will only be valid if the inductor core does not saturate.

The current synthesiser 202 may be used to generate the digitized inductor current DIL using one or more of equations (1) to (7).

The present embodiment relates to a buck converter. However, further embodiments may comprise the current synthesizer 202 for use with current mode switching regulators (all types) using digital loop control. Further embodiments of the current synthesizer 202 can also be used in a conventional switching regulator to obtain a digitally synthesized version of the analog current even if the current is not used in the regulation loop. This may be done for performing other operations like telemetry, load transient detection, and load line modification.

FIG. 2(f) is a schematic of an apparatus 244 comprising a specific embodiment of the current synthesizer 202 in accordance with a fifth embodiment of the present disclosure. The apparatus 244 further comprises a timing controller 246; analog front ends 248, 250; ADCs 252, 254; noise gates 256, 258; a summing circuit 260; an inverter 262; a multiplexer 264. The analog front ends 248, 250 are optional, and may be used for filtering and/or gain.

In a specific embodiment, the input voltage VIN to the switching converter 204, and the output voltage VOUT can be measured using ADCs 252, 254 with an optional analog front end 248, 250. There may be noise gates 256, 258 following each ADC 252, 254 to filter samples that are possibly corrupted by switching of the output stage. The noise gate 256, 258 will filter out samples from the ADC 252, 254 that are too close to the HS/LS switching, using information provided by the timing controller 204 that derives this information from HS (the switch 208) and LS (the switch 218).

In specific embodiments, where the switching converter 204 undergoes an operational phase where both switches 208, 218 are in an off state, the equations above preferably include a diode forward voltage drop and a series resistance that is different from the on resistance of each of the switches 208, 218, and will depend on the direction of the current.

The diode forward voltage will typically relate to the body diode of the pass device (such as the switch 208 or the switch 218). It is possible to add an external diode with a lower forward voltage and/or lower resistance than the body diode instead, in which case the characteristic of that external diode is used.

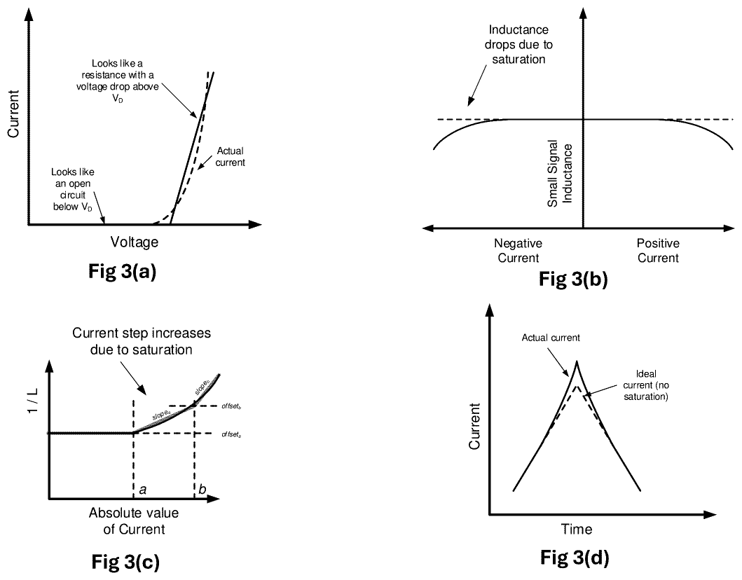

FIG. 3(a) is a current-voltage graph showing a non-linear relationship between voltage and current for a diode. This may be approximated as a voltage drop with resistance and the above equations may be rewritten for the case when both switches are off and the current in the inductor 212 is non-zero, as follows.

If the current is positive, the body diode of the switch 218 will turn on, and the current may be calculated as follows:

$$DI [ n ] = DI [ n - 1 ] - DI [ n - 1 ] ( DCR + RLStrace + RDLS ) \frac{{T}_{S}}{L} + ( - VOUT - VDLS ) \frac{{T}_{S}}{L} \qquad ( 8 )$$

where RDLS is the body diode resistance of the switch 218, VDLS is the voltage across the body diode of the switch 218.

Similarly, if the current is negative (i.e. current is flowing to VIN) current flows through the body diode of the switch 208, and the current may be calculated as follows:

$$DI [ n ] = DI [ n - 1 ] - DI [ n - 1 ] ( DCR + RHStrace + RDHS ) \frac{{T}_{S}}{L} + ( VIN + VDHS - VOUT ) \frac{{T}_{S}}{L} \qquad ( 9 )$$

where RDHS is the body diode resistance of the switch 208, VDHS is the voltage across the body diode of the switch 208.

Once the current hits zero, it is assumed to stay there.

Inductors may saturate, and their apparent inductance to small signal perturbations may appear to decrease as current increases.

FIG. 3(b) is a current-inductance graph showing inductor saturation. Since inductance is used in the form 1/L in the equations above, and since the effect is symmetric, it is sufficient to store a piecewise linear form of one half of 1/L in the form of a lookup table and interpolate the value for different currents. Such data may form the calibration data stored in the lookup tables of any of the embodiments described herein, and in accordance with the understanding of the skilled person.

FIG. 3(c) is a 1/L-current graph showing how interpolation may be applied for different currents.

In a specific embodiment, the inductance L, may be stored directly in the lookup table of the memory storage element 214 and then used to compute the inverse within the current synthesizer 202, depending on which has a lower error for the complete current range.

For a given value of DI, a value of 1/L for use in the calculation to determine the digitized current signal can be computed using an interpolation formula:

$$\frac{1}{L} = offset + slope \times ( \vert DI \vert - offset ) \qquad ( 10 )$$

In a specific embodiment of the present disclosure the inductance L of the inductor 212 may be determined using equation (10) and calibration data stored in a lookup table of the memory storage element 214, where the calibration data has the following format:

| DI | Offset | Slope |
|---|---|---|
| \| DI \| < a | 1/L (original, non-derated) | 0 |
| a <= \| DI \| < b | offsetₐ | slopeₐ |
| b <= \| DI \| | offset_{b} | slope_{b} |

Where the offset and slope are obtained by linear interpolation from offset and slope values in a lookup table. For example, in the above case with just 2 points.

As can be seen the normalized current increase per step increases as the absolute value of current increases.

FIG. 3(d) shows a graph of the current for the switching waveform. The value of L used in all computations above are interpolated using the lookup table and will use the current value of current. As a result, the current for the switching waveform will show a curve instead of the ideal triangular shape as shown in FIG. 3(d).

The 4 equations for current in various modes (switch 208 on, switch 218 on, all off positive current, all off negative current), can be combined in a single equation to obtain the basis for a single computation engine:

$$DI [ n ] = DI [ n - 1 ] - DI [ n - 1 ] \frac{{T}_{S}}{L} ( DCR + {R}_{TRACE} + {R}_{DEV} ) + ( {V}_{SW} - {V}_{OUT} + {V}_{D} ) \frac{{T}_{S}}{L} \qquad ( 11 )$$

Where the values for the following depend on the switch state, and are as provided by the table below:

| | R_{TRACE} | R_{DEV} | V_{SW} | V_{D} |
|---|---|---|---|---|
| Switch 208 on | RHStrace | RHS | VIN | 0 |
| Switch 218 on | RLStrace | RLS | 0 | 0 |
| Off (positive current) | RLStrace | RDLS | 0 | −VDLS |
| Off (negative current) | RHStrace | RDHS | VIN | VDHS |

| | |
|---|---|
| Off (no current) | Keep current at 0 |

As discussed previously, FIG. 2(d) was for an ideal inductor, whereas real inductors (for example with ferromagnetic cores), may exhibit a different variation, such as is shown in FIGS. 3(a)-3(d).

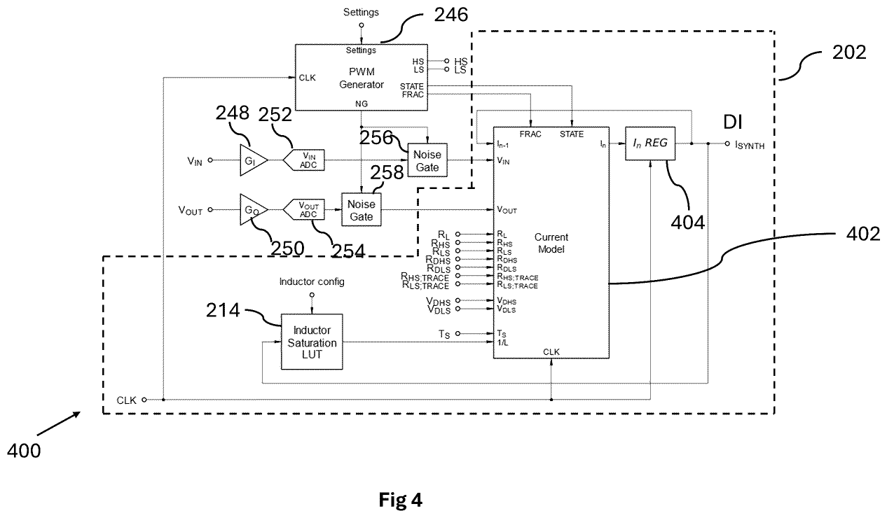

FIG. 4 is a schematic of an apparatus 400 comprising a specific embodiment of the current synthesizer 202 in accordance with a sixth embodiment of the present disclosure. The current synthesizer 202 comprises a computation engine 402 to undertake the calculations of the current as described previously, and a register 404 for storing and output the digitized current signal DI.

In the present example, the timing controller 246 is a PWM generator, that will generate the high side HS and low side LS control signals (previously labelled as GP and GN, respectively), and will provide signals to other blocks in the apparatus 400.

A signal NG outputs to the noise gates 256, 258 and will optionally blank away any portions of the measurement that occur too close to the switching edges. The previously sampled data is preserved in this case. This helps to minimize disruptions to the current calculations due to switching noise.

A signal STATE output from this block will control the current model which uses various input parameters to compute the next value of the synthetic current DI according to equation set noted earlier. The upcoming state of HS/LS to which those outputs will change will be reflected in the STATE, with both changes happening together on the same CLK edge. This will ensure that the current computation on the CLK edge that comes one cycle later will be able to use the STATE for computation of the current at that point in time. The STATE signal is simply an encoding of the state of HS/LS.

The control block 222 may use timing settings that may include delays for the drivers and the output switching devices.

Typically, the optional FRAC output will be necessary when either the edge generation for HS or LS is at a resolution greater than that of the CLK, or when the delays require greater resolution than the CLK period.

The delay information may be used to delay the change of the STATE outputs, and/or to change the value of FRAC provided to the current synthesizer 202. This will reflect the delay in the time when the pass devices 208, 218 state is changed.

The STATE will reflect any change that spans an integer number of cycles and the FRAC will cover the impact of a change within a single cycle using fractional weighting.

FRAC output can be assumed to provide a fractional value between 0 and 1. The transition of the state will then take place at a time FRAC*TS after the CLK edge. If the FRAC output is not generated or used, the effect is equivalent to having a FRAC of 0.

For example, if the transition from HS on to LS on is delayed by FRAC*Tₛ from the CLK edge, the device equivalent resistance R_{DEV} will be as shown below,

$${R}_{DEV} = FRAC . RHS + ( 1 - FRAC ) . RLS \qquad ( 12 )$$

Similar expressions can be derived for all the other terms in the table above, as will be clear to the skilled person.

In a specific embodiment, and as an extension of the above, if a signal changes multiple times during a computation cycle, there may be additional FRAC values from which a weighting can be taken.

In further embodiments, this scheme can be extended to multiple phases by extending the controller, replicating the drivers, switching devices, inductor and/or capacitor, adding one current sensing ADC per additional phase and adding a current synthesizer per additional phase. The voltage ADCs may be shared.

In further embodiments, the correction inputs to the model (e.g. 1/L, and all the resistance terms) can be dynamically changed from cycle to cycle to allow for correction of the synthetic current. This is done by comparing the measured current from the current sense ADC 216 and comparing this against the synthetic current and using the error to change the parameters.

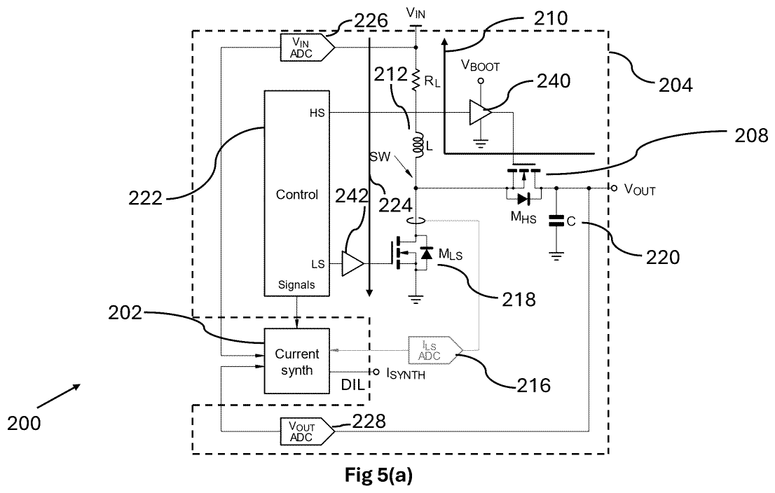

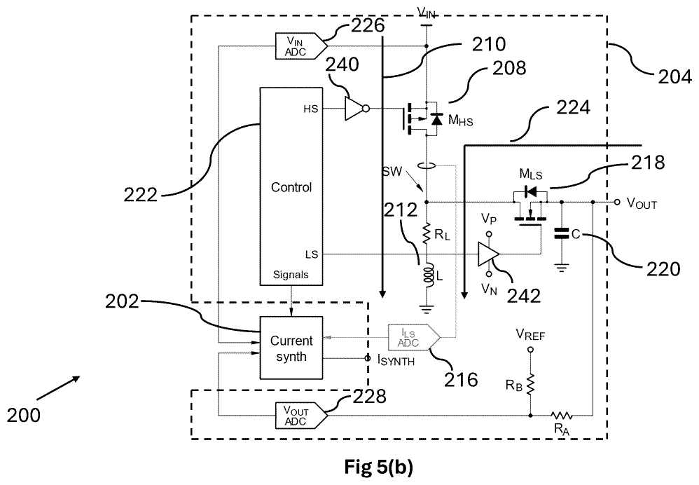

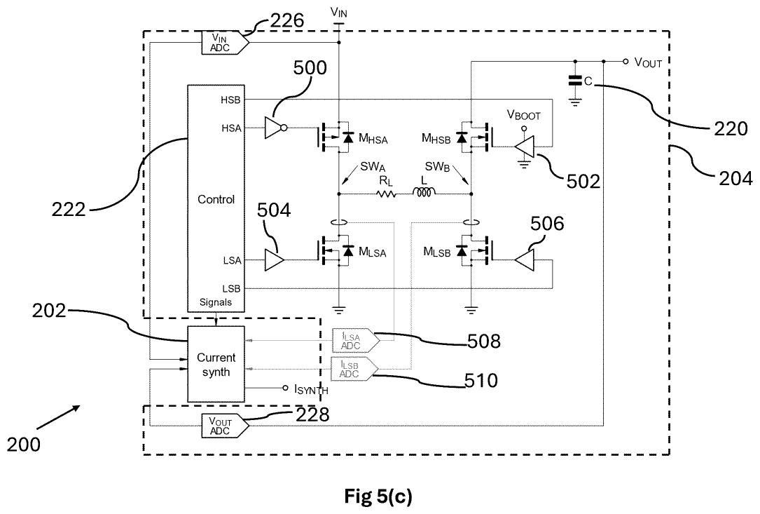

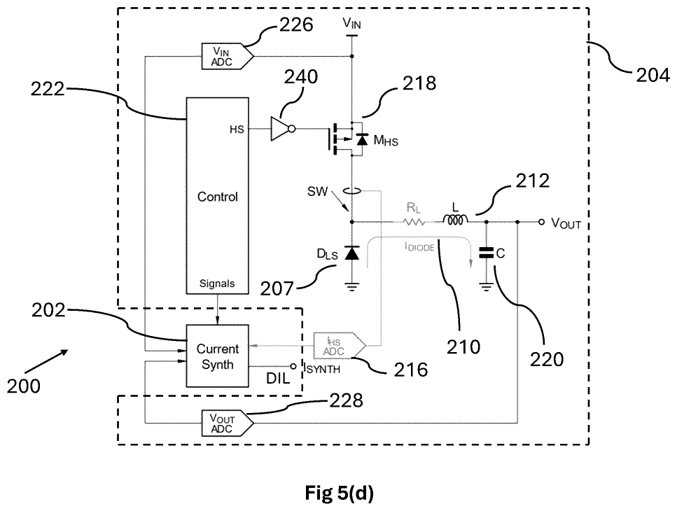

FIG. 5(a) is a schematic of a specific embodiment of the apparatus 200, where the apparatus is a digital boost converter system comprising the switching converter 204 and the current synthesizer 202, in accordance with a seventh embodiment of the present disclosure. In the present embodiment, the switching converter 204 is a boost converter.

In the present embodiment, the boost converter uses an NMOS high side switch (the switch 208) supplied through the driver 240 that is powered by a bootstrapped power source VBOOT to meet the overdrive requirement of the switch 208.

In a further embodiment, there may be provided back-to-back high side switches if the output voltage VOUT must be 0 when the switches are powered off.

The operation of the present embodiment will be clear to the skilled person based on the discussion of the previous embodiments comprising a buck converter.

If only the switch 218 is switched on:

$$DI [ n ] = DI [ n - 1 ] - DI [ n - 1 ] ( DCR + RLS + RLStrace ) \frac{{T}_{S}}{L} + VIN \frac{{T}_{S}}{L} \qquad ( 13 )$$

If only the switch 208 is turned on:

$$DI [ n ] = DI [ n - 1 ] - DI [ n - 1 ] ( DCR + RHS + RHStrace ) \frac{{T}_{S}}{L} + ( VIN - VOUT ) \frac{{T}_{S}}{L} \qquad ( 14 )$$

FIG. 5(b) is a schematic of a specific embodiment of the apparatus 200, where the apparatus is an inverting buck-boost converter system comprising the switching converter 204 and the current synthesizer 202, in accordance with an eighth embodiment of the present disclosure. In the present embodiment, the switching converter 204 is an inverting buck-boost converter.

The operation of the present embodiment will be clear to the skilled person based on the discussion of the previous embodiments comprising a buck converter or a boost converter.

Note that the resistive ladder in front of the VOUT ADC is optional and is used to bring the negative output voltage within the range of VOUT ADC. In this circuit positive current in the inductor is towards ground.

If only the switch 208 is turned on:

$$DI [ n ] = DI [ n - 1 ] - DI [ n - 1 ] ( DCR + RHS + RHStrace ) \frac{{T}_{S}}{L} + VIN \frac{{T}_{S}}{L} \qquad ( 15 )$$

If only the switch 218 is switched on:

$$DI [ n ] = DI [ n - 1 ] - DI [ n - 1 ] ( DCR + RLS + RLStrace ) \frac{{T}_{S}}{L} + VOUT \frac{{T}_{S}}{L} \qquad ( 16 )$$

FIG. 5(c) is a schematic of a specific embodiment of the apparatus 200, where the apparatus is a positive buck-boost converter system comprising the switching converter 204 and the current synthesizer 202, in accordance with a ninth embodiment of the present disclosure. In the present embodiment, the switching converter 204 is a positive buck-boost converter. The switching converter 204 comprises switches M_{HSA}, M_{HSB}, M_{LSA}, M_{LSB}; drivers 500, 502, 504, 506 and current sensors 508, 510.

It will be appreciated by the skilled person that the positive buck-boost of the present embodiment is different from a negative buck-boost (such as the system of FIG. 5(b)) and one of them is not simply a variant of the other.

The current in the inductor is defined as positive when it flows from SWA to SWB and can be computed using:

$$DI [ n ] = DI [ n - 1 ] - DI [ n - 1 ] ( DCR + {R}_{TRACE} + {R}_{DEV} ) \frac{{T}_{S}}{L} + ( {V}_{{SW}_{A}} - {V}_{{SW}_{B}} ) \frac{{T}_{S}}{L} \qquad ( 17 )$$

| | R_{TRACE} | R_{DEV} | V_{SW}_{_{A}} | V_{SW}_{_{B}} |
|---|---|---|---|---|
| M_{HSA} on, M_{LSB} on | R_{HSA; TRACE} + R_{LSB; TRACE} | R_{HSA} + R_{LSB} | V_{IN} | 0 |
| M_{LSA} on, M_{LSB} on | R_{LSA; TRACE} + R_{LSB; TRACE} | R_{LSA} + R_{LSB} | 0 | 0 |
| M_{HSA} on, M_{HSB} on | R_{HSA; TRACE} + R_{HSB; TRACE} | R_{HSA} + R_{HSB} | V_{IN} | V_{OUT} |
| M_{LSA} on, M_{HSB} on | R_{LSA; TRACE} + R_{HSB; TRACE} | R_{LSA} + R_{HSB} | 0 | V_{OUT} |

| | |
|---|---|
| Off (no current) | Keep current at 0 |

In the above cases the diode equations are not explicitly written down, as there would be many of them, but they are all derivable from the buck example, as will be clear to the skilled person.

FIG. 5(d) is a schematic of a specific embodiment of the apparatus 200, where the apparatus is a buck converter system comprising the switching converter 204 and the current synthesizer 202, in accordance with a tenth embodiment of the present disclosure. In the present embodiment, the pass device 207 is a diode D_{LS}.

In further embodiments and in relation to the above examples, current sense ADCs may be placed with any of the pass devices. In specific embodiments, there may be provided only one current sense ADC for each buck, boost, and inverting buck boost, and two current sense ADCs for positive buck boost. However due to duty cycle limits, it is preferable to provide additional current sense ADCs.

In summary, embodiments of the present disclosure may provide a topology dependent current synthesizer that can compute the current in the energy storage element of a switching converter, for example an inductor, based on available information/properties that may include PWM switching information, voltage at various nodes, knowledge of nominal REQ and inductance L, and can include inductance droop and thermal characteristics, body diode characteristics of the pass devices, background calibration data, and fixed calibration data. Embodiments of the present disclosure may use piecewise linear modelling of inductor droop; inductor saturation and diode properties, such as in relation to body diodes, and including diode forward voltage and resistance; and gate drive voltage. It will be appreciated that inductor droop may also be referred to as inductor saturation.

Various improvements and modifications may be made to the above without departing from the scope of the disclosure.

1. A current synthesizer for a switching converter comprising an energy storage element and a first pass device, the switching converter configured to receive an input voltage and to provide an output voltage, the current synthesizer being configured to:
determine one or more first properties of a first current path of the switching converter, the first current path comprising the first pass device and the energy storage element;
calculate a current flow through the energy storage element using the determined one or more first properties; and
generate a digitized current signal, the digitized current signal being a digital representation of the current flow through the energy storage element, as calculated.

2. The current synthesizer of claim 1, wherein the one or more first properties of the first current path comprises:
a first current path resistance;
a first current path voltage; and/or
an inductance of the energy storage element, wherein the energy storage element comprises an inductor.

3. The current synthesizer of claim 2, wherein the first current path resistance comprises an equivalent series resistance of the inductor and a first pass device resistance of the first pass device.

4. The current synthesizer of claim 1, wherein the first pass device is a first power switch or a first diode.

5. The current synthesizer of claim 4, wherein the one or more first properties of the first current path comprises:
a first current path resistance;
a first current path voltage; and/or
an inductance of the energy storage element, wherein the energy storage element comprises an inductor.

6. The current synthesizer of claim 5, wherein the first current path resistance comprises an equivalent series resistance of the inductor and a first power switch resistance of the first power switch.

7. The current synthesizer of claim 6, wherein the first power switch resistance is an on resistance of the first power switch or a body diode resistance of the first power switch.

8. The current synthesizer of claim 2, wherein the first current path voltage comprises the output voltage and a first node voltage.

9. The current synthesizer of claim 8, wherein the switching converter comprises a voltage detector configured to detect the output voltage and the first node voltage.

10. The current synthesizer of claim 2, comprising a memory storage element comprising:
a lookup table for storing calibration data; wherein
at least one of the first current path resistance and the inductance of the inductor are determined using at least a portion of the calibration data.

11. The current synthesizer of claim 10, configured to determine the inductance of the inductor by selecting the at least a portion of the calibration data based on the digitized current signal.

12. The current synthesizer of claim 10, configured to:
determine the first current path resistance using one or both of a gate drive voltage and a temperature value.

13. The current synthesizer of claim 1 configured to:
determine the one or more first properties of the first current path of the switching converter at a first time step;
calculate the current flow through the energy storage element at a second time step using the determined one or more properties at the first time step;
generate the digitized current signal comprising the digital representation of the current flow through the energy storage element at the second time step, as calculated.

14. The current synthesizer of claim 13, wherein the one or more first properties of the first current path comprises:
a first current path resistance;
a first current path voltage; and/or
an inductance of the energy storage element, wherein the energy storage element comprises an inductor.

15. The current synthesizer of claim 14 configured to calculate the current flow through the energy storage element at the second time step by:
determine a first variable by multiplying the first current path resistance at the first time step and the current flow through the energy storage element at the first time step;
determine a second variable by subtracting the first variable from the first current path voltage at the first time step;
determine a third variable by multiplying the second variable with the time step difference between the second and first time steps, and dividing by the inductance; and
determine the current flow through the energy storage element at the second time step by adding the current flow through the energy storage element at the first step to the third variable.

16. The current synthesizer of claim 1 configured to generate the digitized current signal when the switching converter is in at least one of:
a magnetization phase;
a demagnetization phase; and/or
an off phase.

17. The current synthesizer of claim 1, wherein the switching converter comprises a second power switch, the current synthesizer being configured to:
determine the one or more first properties of the first current path of the switching converter during a first phase;
calculate the current flow through the energy storage element using the determined one or more properties during the first phase;
generate a first portion of the digitized current signal during the first phase, using the calculated current flow during the first phase;
determine one or more second properties of a second current path of the switching converter during a second phase, the second path comprising the second power switch and the energy storage element;
calculate the current flow through the energy storage element using the determined one or more second properties; and
generate a second portion of the digitized current signal during the second phase, using the calculated current flow during the second phase.

18. The current synthesizer of claim 17, wherein:
the switching converter comprises a controller configured to provide a second control signal to the second power switch; and
the switching converter is operating in the first phase when the second power switch is in a first configuration and operating in the second phase when the second power switch is in a second configuration.

19. The current synthesizer of claim 17, wherein the one or more first properties of the first current path comprises:
a first current path resistance;
a first current path voltage; and/or
an inductance of the energy storage element, wherein the energy storage element comprises an inductor; and the one or more second properties of the second current path comprises:
a second current path resistance;
a second current path voltage; and/or
the inductance of the energy storage element.

20. The current synthesizer of claim 19, wherein:
the first current path voltage comprises the output voltage and a first node voltage; and/or
the second current path voltage comprises the output voltage and a second node voltage.

21. The current synthesizer of claim 19, comprising a memory storage element comprising:
a lookup table for storing calibration data; wherein
at least one of the first current path resistance, the second current path resistance and the inductance of the inductor are determined using at least a portion of the calibration data.

22. The current synthesizer of claim 21, configured to determine the inductance of the inductor by selecting the at least a portion of the calibration data based on the digitized current signal.

23. A power converter system comprising:
a current synthesizer; and
a switching converter comprising:
an energy storage element and a first pass device, the switching converter configured to receive an input voltage and to provide an output voltage; wherein:
the current synthesizer is configured to:
determine one or more first properties of a first current path of the switching converter, the first current path comprising the first pass device and the energy storage element;
calculate a current flow through the energy storage element using the determined one or more first properties; and
generate a digitized current signal, the digitized current signal being a digital representation of the current flow through the energy storage element, as calculated.

24. A method of generating a digitized current signal using a current synthesizer for a switching converter, the switching converter comprising an energy storage element and a first pass device, the switching converter configured to receive an input voltage and to provide an output voltage, the method comprising:
determining one or more first properties of a first current path of the switching converter, the first current path comprising the first pass device and the energy storage element;
calculating a current flow through the energy storage element using the determined one or more first properties; and
generating the digitized current signal, the digitized current signal being a digital representation of the current flow through the energy storage element, as calculated.
